(19) United States
(12) Patent Application Publication
(10) Pub. No.: US 2025/0104971 A1
(43) Pub. Date: Mar. 27, 2025

(54) PLASMA PROCESSING APPARATUS

(71) Applicant: Tokyo Electron Limited, Minato-ku, Tokyo (JP)

(72) Inventor: Masaki HIRAYAMA, Fuchu City, Tokyo (JP)

(21) Appl. No.: 18/730,100

(22) PCT Filed: Jan. 17, 2023
(86) PCT No.: PCT/JP2023/001233

§ 371 Date: Jul. 18, 2024

(30) Foreign Application Priority Data
Jan. 25, 2022 (JP) 2022-009544

(51) Int. Cl. H01J 37/32; C23C 16/505

(52) U.S. Cl. CPC H01J 37/32183; C23C 16/505

(57) ABSTRACT

In a plasma processing apparatus according to an exemplary embodiment, a processing container is configured to perform plasma processing. A radio-frequency power source is configured to supply a radio frequency to an electrode provided in the processing container. A tubular portion is provided in the processing container. The tubular portion includes a tubular outer conductor, a tubular inner conductor provided inside the tubular outer conductor to be spaced apart from the tubular outer conductor, a dielectric provided between the tubular outer conductor and the tubular inner conductor, and a short-circuit member configured to electrically short-circuit the tubular outer conductor and the tubular inner conductor, and is configured to adjust an impedance of a load side electrically connected to the radio-frequency power source. The tubular outer conductor is electrically connected to the processing container as a grounded conductor. The tubular inner conductor is electrically connected to the electrode.

### TECHNICAL FIELD

Exemplary embodiments of the present disclosure relate to a plasma processing apparatus.

### BACKGROUND

In a plasma processing apparatus used for manufacturing an electronic device, a radio frequency in a VHF band or a UHF band generated by a radio-frequency power source is supplied to a processing space. Techniques relating to the plasma processing apparatus are disclosed in, for example, Patent Documents 1 to 3.

### PRIOR ART DOCUMENTS

### Patent Documents

Patent Document 1: Japanese Laid-Open Publication No. 2018-35443
Patent Document 2: Japanese Laid-Open publication No. 2019-106290
Patent Document 3: Pamphlet of International Publication No. 2013-89007

### SUMMARY

The present disclosure provides a technique for adjusting an impedance of a load side electrically connected to a radio-frequency power source.

According to one exemplary embodiment, a plasma processing apparatus is provided. The plasma processing apparatus includes a processing container, a radio-frequency power source, and a tubular portion. The processing container is configured to perform plasma processing. The radio-frequency power source is configured to supply a radio frequency to an electrode provided in the processing container. The tubular portion is provided in the processing container. The tubular portion includes a tubular outer conductor, a tubular inner conductor provided inside the tubular outer conductor to be spaced apart from the tubular outer conductor, a dielectric provided between the tubular outer conductor and the tubular inner conductor, and a short-circuit member configured to electrically short-circuit the tubular outer conductor and the tubular inner conductor. The tubular portion is configured to adjust an impedance of a load side electrically connected to the radio-frequency power source. The tubular outer conductor is electrically connected to the processing container as a grounded conductor. The tubular inner conductor is electrically connected to the electrode.

According to one exemplary embodiment, it is possible to adjust an impedance of a load side electrically connected to a radio-frequency power source.

### BRIEF DESCRIPTION OF DRAWINGS

FIG. 1 is a diagram illustrating a configuration of a plasma processing apparatus according to one exemplary embodiment.

FIG. 2 is a diagram showing equations representing an impedance provided by a coaxial filter of a tubular portion in FIG. 1.

### DETAILED DESCRIPTION

Hereinafter, various exemplary embodiments will be described.

In recent years, as semiconductor manufacturing technology has advanced, there has been a demand for higher performance of a plasma processing apparatus. In a plasma processing apparatus for film formation such as CVD and ALD, radio frequencies in VHF to UHF bands are used for plasma excitation to improve productivity by increasing the density of active species in a gas phase and reduce damage by lowering energy of ions incident on a substrate surface.

A pipe for introducing gas, a pipe for introducing fluid to keep a temperature of an electrode constant, an electrical wiring of a heater, an electrical wiring for a thermocouple, and the like may be connected to an electrode of the plasma processing apparatus. An insulating portion or a low-pass filter may be used to prevent a radio frequency from leaking to the outside of the plasma processing apparatus via these pipes and wires, that is, to electrically insulate the plasma processing apparatus from the outside of the plasma processing apparatus. When a radio frequency voltage is applied to the insulation portion, plasma may be generated within the pipes. An electric discharge inside the pipes tends to occur more easily as a plasma excitation frequency becomes higher.

On the other hand, a radio frequency output from a matcher connected to a radio-frequency power source propagates through a propagator inside the plasma processing apparatus and is emitted from a radio-frequency emitter into a processing container. In the radio-frequency emitter, since a portion of the radio frequency is reflected and returns toward the matcher, standing waves are generated in the propagator at the frequency of the VHF to UHF bands. Thus, even if a voltage required for plasma ignition is several hundred volts at the radio-frequency emitter, a voltage output from an output part of the matcher may exceed several thousand volts. In this case, the matcher may be affected by the high voltage. Therefore, there is a need for a technique for adjusting an impedance of a load side electrically connected to the radio-frequency power source.

In one exemplary embodiment, there is provided a plasma processing apparatus. The plasma processing apparatus includes a processing container, a radio-frequency power source, and a tubular portion. The processing container is configured to perform plasma processing. The radio-frequency power source is configured to supply a radio frequency to an electrode provided in the processing container. The tubular portion is provided in the processing container. The tubular portion includes a tubular outer conductor, a tubular inner conductor provided inside the tubular outer conductor to be spaced apart from the tubular outer conductor, a dielectric provided between the tubular outer conductor and the tubular inner conductor, and a short-circuit member configured to electrically short-circuit the tubular outer conductor and the tubular inner conductor, and is configured to adjust an impedance of a load side electrically connected to the radio-frequency power source. The tubular outer conductor is electrically connected to the processing container as a grounded conductor. The tubular inner conductor is electrically connected to the electrode.

Therefore, the impedance of the load side electrically connected to the radio-frequency power source may be adjusted by the configuration of the tubular portion.

In one exemplary embodiment, the tubular portion is configured to supplement a reactance component of the impedance of the load side electrically connected to the radio-frequency power source.

In this way, by supplementing the reactance component, it is possible to reduce an influence of the radio frequency generated from the radio-frequency power source on the load side electrically connected to the radio-frequency power source.

In one exemplary embodiment, the short-circuit member is a conductor or a capacitor.

In one exemplary embodiment, the radio-frequency power source supplies, to the electrode, a radio frequency voltage in at least one frequency band of a VHF band, a UHF band, or a microwave band.

In one exemplary embodiment, the tubular portion is configured to introduce utilities including at least one of a gas, a temperature control fluid, or an electrical wiring.

In one exemplary embodiment, the outer conductor extends upward from an upper surface of an upper wall of the processing container. The inner conductor extends upward from the electrode via the upper wall. A space is provided around an outside of the inner conductor to cover the inner conductor.

In one exemplary embodiment, a region extending from a lower surface of the upper wall to an upper side of the upper wall in the space covering the inner conductor is filled with the dielectric.

In one exemplary embodiment, when a wavelength of the radio frequency supplied to the electrode from the radio-frequency power source in the tubular portion is Ag and a length of the region extending from the lower surface of the upper wall to the upper side of the upper wall is L, L is in a range of 0<L<λg/2.

In one exemplary embodiment, the electrode includes a plurality of electrodes, and the inner conductor is electrically connected to each of the plurality of electrodes.

In one exemplary embodiment, the tubular portion includes a plurality of tubular portions.

In one exemplary embodiment, the plurality of tubular portions is disposed on the upper wall of the processing container axially symmetrically with respect to a central axis of the upper wall.

Various exemplary embodiments will now be described below in detail with reference to the drawings. In addition, the same or equivalent parts will be designated by like reference numerals in each drawing.

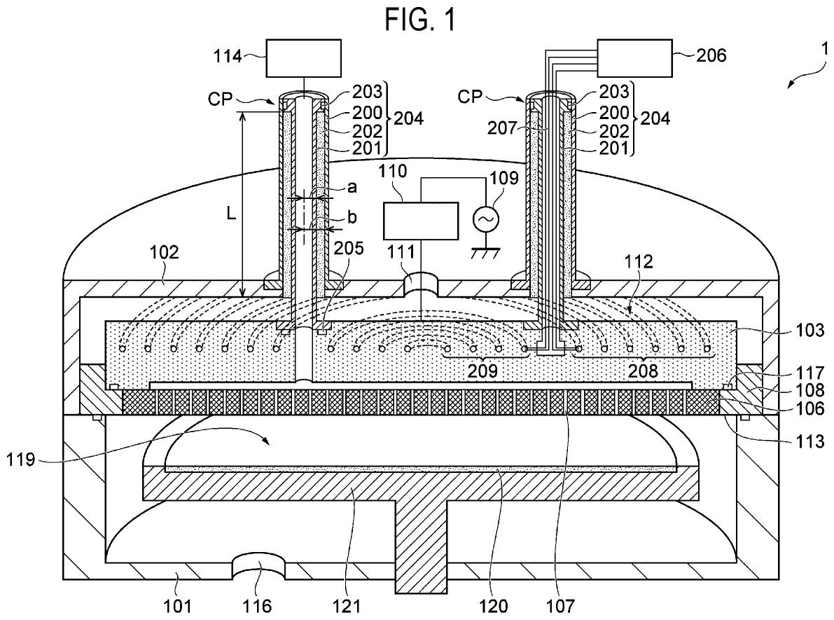

An example of a configuration of a plasma processing apparatus 1 is illustrated in FIG. 1. The configuration of the plasma processing apparatus 1 will now be described with reference to FIG. 1.

The plasma processing apparatus 1 includes a processing container 101, an upper wall 102, an electrode 103, a shower plate 106, a gas hole 107, an insulating ring 108, a radio-frequency power source 109, and a plurality of tubular portions CP.

The plasma processing apparatus 1 further includes a matcher 110, a radio-frequency introduction portion 111, a radio-frequency propagation portion 112, a radio-frequency emitter 113, a gas supplier 114, an exhaust port 116, a sealing member 117, a processing space 119, a substrate 120, and a stage 121.

The plasma processing apparatus 1 further includes an outer conductor 200, an inner conductor 201, a dielectric 202, a short-circuit member 203, a coaxial filter 204, a sealing member 205, a heater power source 206, a heater wiring 207, an outer heater 208, and an inner heater 209.

In the processing container 101, the electrode 103 is provided along the upper wall 102 of the processing container 101 to face the upper wall 102. Two heaters (the outer heater 208 and the inner heater 209) are embedded in the electrode 103. The outer heater 208 and the inner heater 209 may be, for example, sheath heaters.

The radio-frequency power source 109 is electrically connected to the electrode 103 via the matcher 110 and the radio-frequency introduction portion 111 of the upper wall 102. In one embodiment, the radio-frequency introduction portion 111 may be provided with a coaxial waveguide which is not shown. A radio frequency generated from the radio-frequency power source 109 is applied to the electrode 103 via the matcher 110. The radio-frequency propagation portion 112, which is a space in which the radio frequency propagates, is provided between the upper wall 102 and the electrode 103.

In the processing container 101, the electrode 103 is supported by and fixed to the insulating ring 108. The insulating ring 108 is provided along a sidewall of the processing container 101. The sealing member 117 is provided in a bonding surface between the electrode 103 and the insulating ring 108. The sealing member 117 improves airtightness of each of a plurality of spaces (a space of the radio-frequency propagation portion 112 and a space between the electrode 103 and the shower plate 106) defined by bonding the electrode 103 and the insulating ring 108.

The radio-frequency power source 109 is provided in the processing container 101 and is configured to supply the radio frequency to the electrode 103. The radio-frequency power source 109 supplies a radio frequency voltage (hereinafter sometimes referred to as a “radio frequency”) in at least one frequency band of a VHF band, a UHF band, or a microwave band to the electrode 103. The radio frequency output from the radio-frequency power source 109 is introduced into the processing container 101 from the radio-frequency introduction portion 111 via the matcher 110. The radio frequency propagates through the radio-frequency propagation portion 112 surrounding the electrode 103 and is emitted from the radio-frequency emitter 113 into the processing space 119. The radio frequency excites plasma while propagating along a lower surface of the shower plate 106 as a surface wave.

The shower plate 106 is provided below the electrode 103 along the electrode 103. The space is provided between the electrode 103 and the shower plate 106. This space communicates with the tubular portion CP connected to the gas supplier 114 via the electrode 103. Gas output from the gas supplier 114 diffuses into the space between the electrode 103 and the shower plate 106 via the tubular portion CP. This gas is further supplied into the processing space 119 provided below the shower plate 106 via a plurality of gas holes 107 provided in the shower plate 106. Plasma of the gas emitted into the processing space 119 is generated by a radio frequency emitted from the radio-frequency emitter 113 into the processing space 119. The substrate 120 placed on the stage 121 is subjected to plasma processing by this plasma. The gas in the processing space 119 is exhausted to the outside via the exhaust port 116.

The processing container 101 is configured to perform the plasma processing. The processing container 101 is an electrically grounded conductor.

The processing container 101 is provided with the tubular portion CP. The tubular portion CP is configured to adjust an impedance of a load side electrically connected to the radio-frequency power source 109. The tubular portion CP includes the coaxial filter 204. The coaxial filter 204 extends upward from the upper wall 102. The coaxial filter 204 includes the tubular outer conductor 200, the tubular inner conductor 201 provided inside the outer conductor 200 and spaced apart from the outer conductor 200, and the dielectric 202 provided in a space between the outer conductor 200 and the inner conductor 201. An inner diameter b of the outer conductor 200 is larger than an outer diameter a of the inner conductor 201. The dielectric 202 may be a solid member or gas (e.g., air).

The outer conductor 200 is electrically connected to the processing container (particularly the upper wall 102). The outer conductor 200 extends upward from an upper surface of the upper wall 102 of the processing container 101. The inner conductor 201 is electrically connected to the electrode 103. The inner conductor 201 extends upward from the electrode 103 via the upper wall 102. A space that covers the inner conductor 201 is provided around the outside of the inner conductor 201. The sealing member 205 is provided on the bonding surface of the inner conductor 201 and the electrode 103. The sealing member 205 improves airtightness of each of the plurality of spaces (the space of the radio-frequency propagation portion 112 and the space inside the tubular portion CP) defined by bonding of the inner conductor 201 and the inner conductor 201. The coaxial filter 204 is formed by the outer conductor 200, the inner conductor 201, the dielectric 202 provided in the space between the outer conductor 200 and the inner conductor 201, and the space provided around the outside of the inner conductor 201 and covering the inner conductor 201. The sealing member 205 is required for the coaxial filter 204 that guides gas or the like, but is not required for the coaxial filter 204 that guides electrical wiring such as the heater wiring 207 electrically connected to the heater power source 206.

The outer conductor 200 and the inner conductor 201 are formed of a metal such as an aluminum alloy, copper, or stainless steel. The outer conductor 200 and the inner conductor 201 may be coated with gold plating, silver plating, nickel plating, or the like. The tubular portion CP including the coaxial filter 204 may be a bendable tube (coaxial cable).

The tubular portion CP further includes the short-circuit member 203 that electrically short-circuits the outer conductor 200 and the inner conductor 201. In one embodiment, the short-circuit member 203 may be a conductor, such as a spiral ring, or a capacitor, for example. The short-circuit member 203 is provided near upper ends of the outer conductor 200 and the inner conductor 201. The outer conductor 200 and the inner conductor 201 are electrically short-circuited from each other near the upper ends thereof.

The coaxial filter 204 of the tubular portion CP further includes the dielectric 202 provided between the outer conductor 200 and the inner conductor 201. A region extending from the lower surface of the upper wall 102 to an upper side of the upper wall 102 in the space covering the inner conductor 201 is filled with the dielectric 202. The dielectric 202 may be made of an insulating material such as tetrafluoroethylene, aluminum oxide, quartz, or the like. The region extending from the lower surface of the upper wall 102 to the upper side of the upper wall 102 may be filled with gas instead of the dielectric 202.

The tubular portion CP is configured to introduce utilities including at least one of a gas, a temperature control fluid, or an electrical wiring. In the case of the configuration shown in FIG. 1, the gas supplied from the gas supplier 114, and the electrical wiring that electrically connects the heater power source 206 with the outer heater 208 and the inner heater 209 are introduced into the tubular portion CP. Further, the tubular portion CP may be used for a coaxial waveguide (not shown) provided in the radio-frequency introduction portion 111.

In one embodiment, the tubular portion CP, together with the coaxial filter 204, may be a tube that is difficult to deform but may also be a flexible tube. Further, a cross-sectional shape of the tubular portion CP may be a circle but may be another shape such as a rectangle. Further, the inner diameter of the outer conductor 200 and the outer diameter of the inner conductor 201 may be changed during bending.

In one embodiment, the plasma processing apparatus 1 may have a plurality of tubular portions CP. In this case, the plurality of tubular portions CP (the plurality of coaxial filters 204) is disposed on the upper wall 102 axially symmetrically with respect to a central axis of the upper wall 102 in an upper portion of the electrode 103. By arranging the plurality of coaxial filters 204 at axially symmetrical positions, deterioration of a circumferential distribution of plasma due to the introduction of the coaxial filters 204 is suppressed.

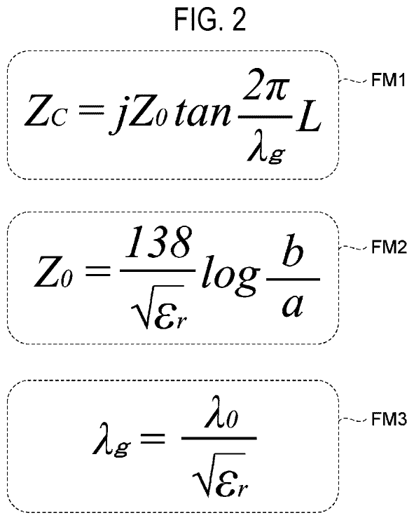

Next, the shape of the tubular portion CP will be described. It is assumed that a wavelength of the radio frequency supplied to the electrode 103 from the radio-frequency power source 109 in the tubular portion CP is Ag and a length of the region extending from the lower surface of the upper wall 102 to the upper side of the upper wall is L. An impedance Zc of the coaxial filter 204 when viewed from the lower end of the coaxial filter 204 (lower surface of the upper wall 102) extending upward from the lower surface of the upper wall 102 is expressed by Equation FM1 shown in FIG. 2.

Z0 denoted in Equation FM1 is a characteristic impedance of the coaxial filter 204 and is expressed by Equation FM2 shown in FIG. 2. εr is a relative dielectric constant of the dielectric 202. λg denoted in Equation FM1 is a wavelength of an electromagnetic wave generated by the radio frequency power source 109 inside the coaxial filter 204 and is expressed by Equation FM3 shown in FIG. 2. λ0 is a wavelength in vacuum, and j is an imaginary number. That is, the impedance Zc of the coaxial filter 204 has only a reactance component.

The impedance Zc of the coaxial filter 204 changes periodically at a period of λg/2 by the length L of the coaxial filter 204. Zc has an inductive reactance component when L<λg/4, and has a capacitive reactance component when λg/2>L>λg/4. Further, Zc becomes insulative when L=λg/4.

Thus, L is in a range 0<L<λg/2. As a result, by adjusting the length L of the coaxial filter 204 of the tubular portion CP, the impedance Zc of the coaxial filter 204 is adjusted. The impedance of the load side electrically connected to the radio-frequency power source 109 is also adjusted. The impedance Zc of the coaxial filter 204 provides only a reactive component, as shown in Equation FM1 of FIG. 2. Therefore, the reactance component of the impedance of the load side electrically connected to the radio-frequency power source 109 may be supplemented (the reactance component may be adjusted (for example, reduced)) by adjusting Zc. More preferably, the reactance component of the impedance of the load side may be eliminated (made zero). In this case, since an alternating current component is blocked in the load side electrically connected to the high-frequency power source 109 including the tubular portion CP, a discharge in the tubular portion CP that may be generated by the radio frequency or an influence of a wave reflected onto the matcher 110 of the radio frequency on the matcher 110 may be avoided. Reflection after plasma ignition may be suppressed by lowering an output voltage of the matcher 110 before the plasma ignition, thereby reducing an electrical load that may occur in the matcher 110 during the plasma ignition and improving power efficiency. Gas, liquid, current, and signals are introduced into the electrode 103 to which the radio frequency voltage is applied via the tubular portion CP including the coaxial filter 204. This eliminates the need for an insulating material or a low-pass filter provided in a configuration for introducing the gas, the liquid, the current, and the signals. Thus, it is possible to prevent the configuration of the plasma processing apparatus 1 from being complicated. Further, it is possible to suppress the discharge inside the insulating portion and the influence on the low-pass filter due to overvoltage.

While various exemplary embodiments have been described above, various omissions, substitutions, and modifications may be made without being limited to the exemplary embodiments described above. In addition, elements of different embodiments can be combined to provide other embodiments.

For example, the plasma processing apparatus 1 may include a plurality of electrodes 103. In this case, the inner conductor 201 is electrically connected to each of the plurality of electrodes 103.

Here, various exemplary embodiments included in the present disclosure are described in [E1] to [E11] below.

### [E1]

A plasma processing apparatus includes: a processing container configured to perform plasma processing; a radio-frequency power source configured to supply a radio frequency to an electrode provided in the processing container; and a tubular portion provided in the processing container. The tubular portion includes a tubular outer conductor, a tubular inner conductor provided inside the tubular outer conductor to be spaced apart from the tubular outer conductor, a dielectric provided between the tubular outer conductor and the tubular inner conductor, and a short-circuit member configured to electrically short-circuit the tubular outer conductor and the tubular inner conductor, and is configured to adjust an impedance of a load side electrically connected to the radio-frequency power source. The tubular outer conductor is electrically connected to the processing container as a grounded conductor. The tubular inner conductor is electrically connected to the electrode.

### [E2]

In the plasma processing apparatus of [E1] above, the tubular portion is configured to supplement a reactance component of the impedance of the load side electrically connected to the radio-frequency power source.

### [E3]

In the plasma processing apparatus of [E1] or [E2] above, the short-circuit member is a conductor or a capacitor.

### [E4]

In the plasma processing apparatus of any one of [E1] to [E3] above, the radio-frequency power source supplies the radio frequency in an at least one frequency band of a VHF band, a UHF band, or a microwave band.

### [E5]

In the plasma processing apparatus of any one of [E1] to [E4] above, the tubular portion is configured to introduce utilities including at least one of a gas, a temperature control fluid, or an electrical wiring.

### [E6]

In the plasma processing apparatus of any one of [E1] to [E5] above, the tubular outer conductor extends upward from an upper surface of an upper wall of the processing container, the tubular inner conductor extends upward from the electrode via the upper wall, and a space is provided around an outside of the tubular inner conductor to cover the tubular inner conductor.

### [E7]

In the plasma processing apparatus of [E6] above, a region extending from a lower surface of the upper wall to an upper side of the upper wall in the space covering the tubular inner conductor is filled with the dielectric.

### [E8]

In the plasma processing apparatus of [E7] above, when a wavelength of the radio frequency supplied to the electrode from the radio-frequency power source in the tubular portion is λg and a length of the region extending from the lower surface of the upper wall to the upper side of the upper wall is L, L is in a range of 0<L<λg/2.

### [E9]

In the plasma processing apparatus of any one of [E1] to [E8] above, the electrode includes a plurality of electrodes, and the tubular inner conductor is electrically connected to each of the plurality of electrodes.

### [E10]

In the plasma processing apparatus of any one of [E1] to [E9] above, the tubular portion includes a plurality of tubular portions.

### [E11]

In the plasma processing apparatus of [E10] above, the plurality of tubular portions is disposed on the upper wall of the processing container axially symmetrically with respect to a central axis of the upper wall.

From the foregoing, it should be understood that various exemplary embodiments of the present disclosure have been described herein for purposes of illustration, and that various modifications can be made without departing from the scope and spirit of the present disclosure. Accordingly, the various exemplary embodiments disclosed herein are not intended to be limiting, and the true scope and spirit thereof are represented by the appended claims.

### EXPLANATION OF REFERENCE NUMERALS

1: plasma processing apparatus, 101: processing container, 102: upper wall, 103: electrode, 106: shower plate, 107: gas hole, 108: insulating ring, 109: radio-frequency power source, 110: matcher, 111: radio-frequency introduction portion, 112: radio-frequency propagation portion, 113: radio-frequency emitter, 114: gas supplier, 116: exhaust port, 117: sealing member, 119: processing space, 120: substrate, 121: stage, 200: outer conductor, 201: inner conductor, 202: dielectric, 203: short-circuit member, 204: coaxial filter, 205: sealing member, 206: heater power source, 207: heater wire, 208: outer heater, 209: inner heater, CP: tubular portion

1. A plasma processing apparatus, comprising:
a processing container configured to perform plasma processing;
a radio-frequency power source configured to supply a radio frequency to an electrode provided in the processing container; and
a tubular portion provided in the processing container,
wherein the tubular portion includes a tubular outer conductor, a tubular inner conductor provided inside the tubular outer conductor to be spaced apart from the tubular outer conductor, a dielectric provided between the tubular outer conductor and the tubular inner conductor, and a short-circuit member configured to electrically short-circuit the tubular outer conductor and the tubular inner conductor, and is configured to adjust an impedance of a load side electrically connected to the radio-frequency power source, and
wherein the tubular outer conductor is electrically connected to the processing container as a grounded conductor, and
wherein the tubular inner conductor is electrically connected to the electrode.

2. The plasma processing apparatus of claim 1, wherein the tubular portion is configured to supplement a reactance component of the impedance of the load side electrically connected to the radio-frequency power source.

3. The plasma processing apparatus of claim 1, wherein the short-circuit member is a conductor or a capacitor.

4. The plasma processing apparatus of claim 1, wherein the radio-frequency power source supplies the radio frequency in an at least one frequency band of a VHF band, a UHF band, or a microwave band.

5. The plasma processing apparatus of claim 1, wherein the tubular portion is configured to introduce utilities including at least one of a gas, a temperature control fluid, or an electrical wiring.

6. The plasma processing apparatus of claim 1, wherein the tubular outer conductor extends upward from an upper surface of an upper wall of the processing container,
wherein the tubular inner conductor extends upward from the electrode via the upper wall, and
wherein a space is provided around an outside of the tubular inner conductor to cover the tubular inner conductor.

7. The plasma processing apparatus of claim 6, wherein a region extending from a lower surface of the upper wall to an upper side of the upper wall in the space covering the tubular inner conductor is filled with the dielectric.

8. The plasma processing apparatus of claim 7, wherein when a wavelength of the radio frequency supplied to the electrode from the radio-frequency power source in the tubular portion is Ag and a length of the region extending from the lower surface of the upper wall to the upper side of the upper wall is L, L is in a range of 0<L<λg/2.

9. The plasma processing apparatus of claim 1, wherein the electrode includes a plurality of electrodes, and
wherein the tubular inner conductor is electrically connected to each of the plurality of electrodes.

10. The plasma processing apparatus of claim 1, wherein the tubular portion includes a plurality of tubular portions.

11. The plasma processing apparatus of claim 10, wherein the plurality of tubular portions is disposed on the upper wall of the processing container axially symmetrically with respect to a central axis of the upper wall.
